(19) United States
(12) Patent Application Publication
(10) Pub. No.: US 2024/0425780 A1
(43) Pub. Date: Dec. 26, 2024

(54) CLEANING SOLUTION, METHOD FOR CLEANING SEMICONDUCTOR SUBSTRATE, AND METHOD FOR MANUFACTURING SEMICONDUCTOR

(71) Applicant: TOKYO OHKA KOGYO CO., LTD., Kanagawa (JP)

(72) Inventors: Kenji SEKI, Kanagawa (JP); Jun IIOKA, Kanagawa (JP)

(21) Appl. No.: 18/747,824

(22) Filed: Jun. 19, 2024

Related U.S. Application Data
(60) Provisional application No. 63/509,930, filed on Jun. 23, 2023.

(51) Int. Cl. C11D 3/20; C11D 3/43

(52) U.S. Cl. CPC C11D 3/2082; C11D 3/43; C11D 2111/22

(57) ABSTRACT

There are provided a cleaning solution, including: an oxoacid having an acid dissociation constant pka of less than 5.0 and a valence of two or more, in which a value of pH of the cleaning solution is smaller than the acid dissociation constant; a method for cleaning a semiconductor substrate using the same; and a method for manufacturing a semiconductor.

### TECHNICAL FIELD

The present invention relates to a cleaning solution, a method for cleaning a semiconductor substrate, and a method for manufacturing a semiconductor.

### BACKGROUND ART

In a wiring forming step, for example, a substrate, a metal wiring layer, and an interlayer insulating film which is silicon-based or the like are laminated in this order; a hard mask layer (HM layer) is formed on the interlayer insulating film; and the hard mask layer is etched to form a basic shape of a wiring pattern. As a material of the mask layer, for example, titanium or a titanium-based alloy such as titanium nitride (TiN), titanium oxide (TiOₓ (x represents a number)), etc. is used.

Next, the interlayer insulating film is dry-etched using the etched HM layer as a mask layer to produce a wiring pattern such as a metal wiring and the like.

On an element (for example, substrate/metal wiring layer/interlayer insulating film/HM layer) after the dry etching, a titanium-based residue (residue containing titanium or a titanium-based alloy) derived from the HM layer and an inorganic substance-containing residue derived from the metal wiring layer are adhered.

Dry etching residues are conventionally removed by a cleaning processing. As a cleaning solution to remove dry etching residues, a cleaning solution containing a peroxide as a residue removing agent is used (for example, see Patent Document 1). In addition, a cleaning solution containing hydroxylamine as a residue removing agent, a cleaning solution containing hydrogen fluoride, and the like are used.

### PATENT DOCUMENT

[Patent Document 1] International Publication No. WO2016/076033

### SUMMARY OF THE INVENTION

The present inventors conducted a detailed study on components commonly used as a cleaning solution, such as hydrogen peroxide, hydrogen fluoride, hydroxylamine, etc. As a result, the present inventors have found that cleaning solutions containing these as a main component surprisingly have room for improvement in achieving both removal of a titanium-based residue (residue containing titanium or a titanium-based alloy) and anti-corrosion properties.

Furthermore, as a result of various studies on components that are used as a cleaning solution other than those mentioned above, the present inventors have found that there is also still room for improvement in achieving both removal of a titanium-based residue and anti-corrosion properties.

The present invention has been made in view of the above circumstances, and it is an object of the present invention to provide a cleaning solution that can efficiently remove a titanium-based residue and has excellent anti-corrosion properties, a method for cleaning a semiconductor substrate using the same, and a method for manufacturing a semiconductor.

As a result of intensive studies to achieve the above object, the present inventors have found a cleaning solution that includes an oxoacid having an acid dissociation constant pKa of less than 5.0 and a valence of two or more, in which a value of pH of the cleaning solution is smaller than the acid dissociation constant, and have thus completed the present invention.

[1] A cleaning solution, including: an oxoacid having an acid dissociation constant pKa of less than 5.0 and a valence of two or more, in which a value of pH of the cleaning solution is smaller than the acid dissociation constant.
[2] The cleaning solution according to [1], in which the value of pH of the cleaning solution is 5.0 or less.
[3] The cleaning solution according to [1], in which the oxoacid is at least one selected from the group consisting of oxalic acid, malonic acid, H₃PO₄, and sulfuric acid.
[4] The cleaning solution according to [1], in which a concentration of the oxoacid is from 0.005 to 20% by mass.
[5] The cleaning solution according to [1], further including: at least one selected from the group consisting of a nitrogen-containing heterocycle-containing compound, a mercapto group-containing compound, an aliphatic amine compound, a zwitterionic compound, and a salt thereof, as an anticorrosive agent.
[6] The cleaning solution according to [1], further including: water as a solvent.
[7] The cleaning solution according to [1], further including: at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent, as a solvent.
[8] The cleaning solution according to [1], in which the cleaning solution does not contain hydrogen peroxide, hydrogen fluoride, and hydroxylamine.
[9] The cleaning solution according to [1], in which the cleaning solution is a cleaning solution for a semiconductor substrate; the semiconductor substrate includes a substrate, and a film formed on the substrate; and the film includes titanium or a titanium-based alloy.
[10] A method for cleaning a semiconductor substrate having a protective film, including: removing an impurity from the semiconductor substrate by bringing the cleaning solution according to [1] into contact with the protective film.
[11] A method for manufacturing a semiconductor, including: preparing a substrate having a protective film; etching the protective film; and after the etching, removing an impurity from the substrate by bringing the cleaning solution according to [1] into contact with the substrate.

The present invention can provide a cleaning solution that can efficiently remove a titanium-based residue and has excellent anti-corrosion properties, a method for cleaning a semiconductor substrate using the same, and a method for manufacturing a semiconductor.

### BRIEF DESCRIPTION OF THE DRAWINGS

FIG. 1 is a cross-sectional view illustrating an exemplary element to be cleaned after dry etching.

### DETAILED DESCRIPTION OF THE INVENTION

Hereinafter, an embodiment for carrying out the present invention (hereinafter simply referred to as “the present embodiment”) will be described in detail. The present embodiment below is an example for explaining the present invention, and it is not intended to limit the present invention to the following description. The present invention may be implemented with any appropriate modification within the scope of its gist.

In the drawings, the same elements are denoted by the same reference signs, and duplicate description will be omitted. In addition, the positional relationships such as top, bottom, left, and right are based on those illustrated in the drawings unless otherwise specified. Further, the dimensional ratios in the drawings are not limited to the illustrated ratios.

### <Cleaning Solution>

A cleaning solution according to the present embodiment is a cleaning solution, including: an oxoacid having an acid dissociation constant pka of less than 5.0 and a valence of two or more, in which a value of pH of the cleaning solution is smaller than the acid dissociation constant. By using a cleaning solution that satisfies these conditions, a titanium-based residue can be efficiently removed and excellent anti-corrosion properties can be achieved. Note that the titanium-based residue refers to a residue containing titanium or a titanium-based alloy. The titanium-based alloy refers to a form in which titanium, which is a metal, is bonded with a metal element other than titanium or a non-metal element. Although details will be described later, examples of the titanium-based alloy may include titanium nitride (TiN), titanium oxide (TiOₓ (x represents a number), titanium oxynitride (TiON), titanium oxyfluoride (TiOF), and the like.

The cleaning solution according to the present embodiment can be suitably used as a cleaning solution for removing an etching residue containing an inorganic substance. In that case, it can be suitably used as a cleaning solution for cleaning a semiconductor, etc.

The inorganic substance herein refers to a compound containing a metal, and examples thereof may include a metal, a metal oxide, a metal nitride, a metal chloride, a metal fluoride, and the like. Examples of the inorganic substance other than metals may include silicon (Si), an oxide thereof, and the like. That is, the cleaning solution according to the present embodiment can efficiently remove an etching residue containing such an inorganic substance.

More specifically, the cleaning solution according to the present embodiment can efficiently remove a titanium-based residue (residue containing titanium or a titanium-based alloy) contained in the HM layer and another layer. In addition, the cleaning solution according to the present embodiment is also expected to efficiently remove an inorganic substance-containing residue that is derived from the metal wiring layer and contains one selected from the group consisting of a metal described below, and a metal oxide, a metal nitride, a metal chloride, and a metal fluoride thereof.

Examples of the metal may include one of metals selected from the group consisting of molybdenum (Mo), tungsten (W), ruthenium (Ru), copper (Cu), gold (Au), silver (Ag), iron (Fe), nickel (Ni), aluminum (Al), lead (Pb), zinc (Zn), tin (Sn), tantalum (Ta), magnesium (Mg), cobalt (Co), bismuth (Bi), cadmium (Cd), titanium (Ti), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), thallium (Tl), etc.; a metal oxide, a metal nitride, a metal chloride, a metal fluoride, etc. thereof; and the like.

Examples of the metal oxide may include a metal oxide of the metal atoms described above. Specific examples of the metal oxide may include, but are not limited to, TiOₓ, TaOₓ, CuOₓ, CoOₓ, RuOₓ, AlOₓ, WOₓ, MOOₓ, AuOₓ, AgOₓ, FeOₓ, NiOₓ, and the like (Unless otherwise specified, x represents a number).

Examples of the metal nitride may include a metal nitride of the metal atoms described above. Specific examples of the metal nitride may include, but are not limited to, TiNₓ, TaNₓ, CuNₓ, CONₓ, RuNₓ, AlNₓ, WNₓ, MONₓ, AuNₓ, AgNₓ, FeNₓ, NiNₓ, and the like.

Examples of the metal chloride may include a metal chloride of the metal atoms described above. Specific examples of the metal chloride may include, but are not limited to, TiClₓ, TaClₓ, CuClₓ, CoClₓ, RuClₓ, AlClₓ, WClₓ, MoClₓ, AuClₓ, AgClₓ, FeClₓ, NiClₓ, and the like.

Examples of the metal fluoride may include a metal fluoride of the metal atoms described above. Specific examples of the metal fluoride may include, but are not limited to, TiFₓ, TaFₓ, CuFₓ, CoFₓ, RuFₓ, AlFₓ, WFₓ, MOFₓ, AuFₓ, AgFₓ, FeFₓ, NiFₓ, and the like.

The cleaning solution according to the present embodiment is suitable for removing an etching residue, and in particular it is more suitable for removing a dry etching residue. Usually, from the viewpoint of improving the yield of a semiconductor and preventing deterioration of electrical characteristics thereof, a dry etching residue is removed before the next step. For example, the cleaning solution according to the present embodiment is suitable for cleaning a semiconductor substrate after dry etching is performed in a wiring process.

For example, the cleaning solution according to the present embodiment can suitably remove a residue containing titanium or a titanium-based alloy derived from the HM layer and an etching residue containing an inorganic substance derived from the metal wiring layer, which are adhered in the wiring process. In particular, a titanium-based residue adhered on a semiconductor substrate after dry etching is a residue that has high wet resistance and is difficult to be removed by cleaning processing. The cleaning solution according to the present embodiment can also efficiently clean such a residue.

### (Oxoacid)

An “oxoacid” contained in the cleaning solution according to the present embodiment refers to a compound having a hydroxy group (—OH) capable of donating a proton. The valence of an oxoacid refers to the number of protons that can be donated (released) from the molecule. In the present embodiment, an oxoacid having a valence of two or more is used.

Although the reason that a titanium-based residue can be efficiently removed in the cleaning solution according to the present embodiment is not certain, it is presumed as follows. Since the oxoacid contained in the cleaning solution can have a strong interaction force with a titanium atom contained in the residue, the oxoacid can retain the titanium atom. It is presumed that the cleaning solution can therefore efficiently remove the titanium-based residue (However, the mechanism according to the present embodiment is not limited thereto).

The valence of the oxoacid may be any as long as it is 2 or more. The upper limit of the valence of the oxoacid is not particularly limited, but is preferably 5 or less, more preferably 4 or less, and even more preferably 3 or less. Due to the oxoacid having these valences, a titanium-based residue can be removed more efficiently. Although the reason therefor is not certain, it is presumed as follows. It is considered that when an oxoacid having a specific pka value described above is present in the cleaning solution having a specific pH value described above, and the oxoacid has a valence described above, the above-mentioned interaction force with a titanium atom becomes stronger. It is presumed that the oxoacid can therefore retain the titanium atom more securely, and the cleaning solution can remove the titanium-based residue more efficiently (However, the mechanism according to the present embodiment is not limited thereto).

Specific examples of the oxoacid may include carboxylic acids, boric acid (H₃BO₃, B(OH)₃), carbonic acid (H₂CO₃), ortho carbonic acid (H₄CO₄, C(OH)₄CH₄O₄), carboxylic acid, halogen-oxoacids (hypochlorous acid, chlorous acid, chloric acid, perchloric acid, hypobromous acid, bromous acid, bromic acid, perbromic acid, hypoiodous acid, iodite acid, iodic acid, periodic acid, and the like), silicic acid, nitrous acid (HNO₂), nitric acid, phosphoric acid (H₃PO₄, H₄P₂O₇, HPO₃), phosphorous acid (H₃PO₃), sulfuric acid, sulfurous acid, sulfonic acids, sulfinic acids, and the like. The cleaning solution according to the present embodiment may contain a salt of these oxoacids as the oxoacid (for example, a sodium salt, a potassium salt, a calcium salt, a barium salt, an ammonium salt, a tetraalkylammonium salt, etc.).

The carboxylic acids are each an acid having at least one carboxy group (—COOH). Specific examples of the carboxylic acid may include monocarboxylic acids such as formic acid, acetic acid, propionic acid, butyric acid, valeric acid, etc.; dicarboxylic acids such as oxalic acid, malonic acid, succinic acid, glutaric acid, adipic acid, etc.; tricarboxylic acids such as citric acid, etc.; and the like.

Examples of the halogen-oxoacids may include hypochlorous acid, chlorous acid, chloric acid, perchloric acid, hypobromous acid, bromous acid, bromic acid, perbromic acid, hypoiodous acid, iodite acid, iodic acid, periodic acid, and the like.

The sulfonic acids are each an acid having at least one sulfo group (—SO₃H). Specific examples of the sulfonic acid may include methanesulfonic acid, trifluorosulfonic acid, benzenesulfonic acid, p-toluenesulfonic acid, and the like.

Among the above oxoacids, the oxoacid is preferably at least one selected from the group consisting of carboxylic acids, phosphoric acid (H₃PO₄, H₄P₂O₇, HPO₃), phosphorous acid (H₃PO₃), sulfuric acid, sulfurous acid, and nitric acid; more preferably, at least one selected from the group consisting of carboxylic acids, phosphoric acid (H₃PO₄, H₄P₂O₇, HPO₃), sulfuric acid, and nitric acid; and even more preferably at least one selected from the group consisting of oxalic acid, malonic acid, H₃PO₄, and sulfuric acid.

In the cleaning solution according to the present embodiment, one of the above-described oxoacids may be used alone, or two or more kinds thereof may be used in combination.

The acid dissociation constant of the oxoacid may be any as long as it is less than 5.0. The upper limit of the acid dissociation constant is preferably 5.0 or less, and more preferably 3.0 or less. The lower limit of the acid dissociation constant is not particularly limited, but is preferably −5.0 or more, and more preferably −3.0 or more.

The “acid dissociation constant” according to the present embodiment is one of indexes representing the strength of the acid in a substance, and refers to an acid dissociation constant (pKa) in water at 22° C. For example, in the case of the dissociation parallel reaction represented by the following equation (i), the acid dissociation constant represents the value of pka=−log₁₀Ka with Ka=[H⁺][A⁻]/[HA]. In addition, in the case of a substance that undergoes two or more stages of multi-step dissociation, the first stage of dissociation (first dissociation) is taken into consideration. The pKa value of the present embodiment can be obtained by “Sparc Calculator” (archemcalc.com) operated by Archem Inc. on the Internet (Reference URL: http://archemcalc.com/sparc-web/calc#/multiproperty).

HA⇄H⁺+A⁻ (i)

Further, in the present embodiment, when two or more kinds of oxoacid are used in combination, a weighted average value obtained by multiplying the acid dissociation constant of each oxoacid by the content ratio (mass ratio) is employed. For example, in the case of a cleaning solution containing Oxoacid A and Oxoacid B at the content ratio of 3:1, when the acid dissociation constant of Oxoacid A is 2.0 and the acid dissociation constant of Oxoacid B is 1.0, the weighted average value of the acid dissociation constant is: 2.0×(¾)+1.0×(¼)=1.75.

As examples, Table 1 below shows the acid dissociation constant of each oxoacid calculated based on the “Sparc Calculator” (archemcalc.com) operated by Archem Inc. on the web (The oxoacid that can be used in the present embodiment is not limited to the following).

TABLE 1

| Substance name | [HA] | pKa value |
|---|---|---|
| Oxalic acid (1) | HOOC—COOH | 1.3 |
| Oxalic acid (2) | HOOC—COO⁻ | 3.73 |
| Phosphoric acid (1) | H₃PO₄ | 1.75 |
| Phosphoric acid (2) | H₂PO₄⁻ | 7.08 |
| Phosphoric acid (3) | HPO₄²⁻ | >14 |
| Sulfuric acid (1) | H₂SO₄ | 0.81 |
| Sulfuric acid (2) | HSO₄⁻ | >14 |
| Carbonic acid (1) | H₂CO₃(CO₂ + H₂O) | 3.25 |
| Carbonic acid (2) | HCO₃⁻ | >14 |
| Salicylic acid (1) | C₆H₄(OH)COOH | 3.08 |
| Salicylic acid (2) | C₆H₄(OH)COO⁻ | 13.09 |
| Malonic acid (1) | HOOC—CH₂—COOH | 2.67 |
| Malonic acid (2) | HOOC—CH₂—COO⁻ | 5.26 |
| Citric acid (1) | C₆H₇O₇ | 2.84 |
| Citric acid (2) | C₆H₆O₇⁻ | 4.41 |
| Citric acid (3) | C₆H₅O₇²⁻ | 5.19 |
| Phosphonic acid (1) | HPO(OH)₂ | 1.76 |
| Phosphonic acid (2) | HPO(OH)O⁻ | >14 |
| Salicylhydroxamic acid (1) | C₆H₄(OH)CONHOH | 7.85 |
| Salicylhydroxamic acid (2) | C₆H₄(OH)CONHO⁻ | 10.25 |

The pH value of the cleaning solution according to the present embodiment is smaller than the acid dissociation constant. The upper limit of the pH value is not particularly limited, but is preferably 5.0 or less, more preferably less than 5.0, and even more preferably less than 4.9. The lower limit of the pH value is not particularly limited, but is preferably −5 or more, more preferably −3 or more, even more preferably −1 or more, and still even more preferably a value greater than 0.

The pH value of the cleaning solution in the present embodiment refers to a pH value of the cleaning solution at normal pressure (1 atm) and 22° C. The pH value can be measured, for example, by the method described in the Examples below.

The concentration of the oxoacid in the cleaning solution according to the present embodiment is not particularly limited, but is preferably from 0.005 to 20% by mass. The upper limit of the concentration of the oxoacid is more preferably 18% by mass or less, and even more preferably 15% by mass or less. The lower limit of the concentration of the oxoacid is more preferably 0.01% by mass or more, and even more preferably 0.1% by mass or more. When the content of the oxoacid is equal to or higher than the lower limit described above, the removability of a dry etching residue can be further enhanced in the cleaning processing. On the other hand, when the content of the oxoacid is equal to or lower than the upper limit described above, damage to a metal wiring and the like can be further suppressed.

The cleaning solution according to the present embodiment preferably does not contain hydrogen peroxide. Further, the cleaning solution according to the present embodiment preferably does not contain hydrogen fluoride. In addition, the cleaning solution according to the present embodiment preferably does not contain hydroxylamine. From these viewpoints, the cleaning solution according to the present embodiment more preferably does not contain hydrogen peroxide, hydrogen fluoride, and hydroxylamine.

From the viewpoints described above, the cleaning solution according to the present embodiment preferably does not contain hydrofluoric acid (aqueous solution of hydrogen fluoride), hydrogen peroxide solution (aqueous solution of hydrogen peroxide), and the like.

The cleaning solution according to the present embodiment can be sufficiently expected to obtain the predetermined effects even if it does not contain any optional component other than oxoacid. Therefore, the cleaning solution according to the present embodiment may contain or may not contain any component other than oxoacid, as necessary. For example, it preferably further contains an anticorrosive agent. Except for the anticorrosive agent, the cleaning solution according to the present embodiment may further contain a pH adjuster, a surfactant, a solvent, and the like, but it may not contain these components since a sufficient effect can be expected even if these are not contained. Further, the cleaning solution according to the present embodiment may contain a metal impurity described later as long as an mechanism or effect thereof can be obtained.

### (Anticorrosive Agent)

Specific examples of the anticorrosive agent may include, but are not particularly limited to, at least one selected from the group consisting of a nitrogen-containing heterocyclic ring-containing compound, a mercapto group-containing compound, an aliphatic amine compound, a zwitterionic compound, and a salt thereof. The cleaning solution according to the present embodiment preferably includes one selected from the group.

Specific examples of the nitrogen-containing heterocyclic ring-containing compound may include an imidazole ring-containing compound, a triazole ring-containing compound, a pyridine ring-containing compound, a pyrimidine ring-containing compound, a phenanthroline ring-containing compound, a tetrazole ring-containing compound, a pyrazole ring-containing compound, a purine ring-containing compound, and the like. Among them, the tetrazole ring-containing compound is preferable. By using the tetrazole ring-containing compound, for example, the anti-corrosion properties of a layer containing a metal component such as cobalt, copper, etc. as a main component (for example, a metal wiring layer 20, an etching stop layer 30, an interlayer insulating film 40, or another functional layer, etc.) can be further improved. That is, when the cleaning solution according to the present embodiment is used, damage (film loss) caused to the layer containing cobalt, copper, etc. can be more effectively reduced.

Specific examples of the imidazole ring-containing compound may include 1-decyl-3-methylimidazolium chloride, 2-ethyl-4-methylimidazole, 2-methylimidazole, 2-ethylimidazole, 2-isopropylimidazole, 2-propylimidazole, 2-butylimidazole, 4-methylimidazole, 2,4-dimethylimidazole, 2-undecylimidazole, 2-aminoimidazole, 2,2′-biimidazole, and the like.

Specific examples of the triazole ring-containing compound may include 1,2,4-triazole, 1,2,3-benzotriazole, 1,2,3-triazole, 3-amino-1H-1,2,4-triazole, 5-methyl-1H-benzotriazole, 1-hydroxybenzotriazole, 1-dihydroxypropylbenzotriazole, 2,3-dicarboxypropylbenzotriazole, 4-hydroxybenzotriazole, 4-carboxyl-1H-benzotriazole, 4-carboxyl-1H-benzotriazole methyl ester, 4-carboxyl-1H-benzotriazole butyl ester, 4-carboxyl-1H-benzotriazole octyl ester, 5-hexylbenzotriazole, [1,2,3-benzotriazolyl-1-methyl][1,2,4-triazolyl-1-methyl][2-ethylhexyl]amine, tolyltriazole, naphthotriazole, bis[(1-benzotriazolyl)methyl]phosphonic acid, 3-aminotriazole, and the like.

Specific examples of the pyridine ring-containing compound may include 1H-1,2,3-triazolo[4,5-b]pyridine, 1,2,4-triazolo[4,3-a]pyridin-3(2H)-one, 3H-1,2,3-triazolo[4,5-b]pyridin-3-ol, 1-acetyl-1H-1,2,3-triazolo[4,5-b]pyridine, 3-aminopyridine, 4-aminopyridine, 3-hydroxypyridine, 4-hydroxypyridine, 2-acetamidopyridine, 4-pyrrolidinopyridine, 2-cyanopyridine, 2,2′-bipyridyl, 4,4′-dimethyl-2,2′-bipyridyl, 4,4′-di-tert-butyl-2,2′-bipyridyl, 4,4′-dinonyl-2,2′-bipyridyl, and the like.

Specific examples of the pyrimidine ring-containing compound may include pyrimidine, 1,2,4-triazolo[1,5-a]pyrimidine, 1,3,4,6,7,8-hexahydro-2H-pyrimido[1,2-a]pyrimidine, 1,3-diphenyl-pyrimidine-2,4,6-trione, 1,4,5,6-tetrahydropyrimidine, 2,4,5,6-tetraaminopyrimidine sulfate, 2,4,5-trihydroxypyrimidine, 2,4,6-triaminopyrimidine, 2,4,6-trichloropyrimidine, 2,4,6-trimethoxypyrimidine, 2,4,6-triphenylpyrimidine, 2,4-diamino-6-hydroxypyrimidine, 2,4-diaminopyrimidine, 2-acetamidopyrimidine, 2-aminopyrimidine, 2-methyl-5,7-diphenyl-(1,2,4)triazolo (1,5-a)pyrimidine, 2-methylsulfanyl-5,7-diphenyl-(1,2,4)triazolo (1,5-a)pyrimidine, 2-methylsulfanyl-5,7-diphenyl-4,7-dihydro-(1,2,4)triazolo(1,5-a)pyrimidine, 4-aminopyrazolo[3,4-d]pyrimidine, and the like.

Specific examples of the phenanthroline ring-containing compound may include 1,10-phenanthroline and the like.

Specific examples of the tetrazole ring-containing compound may include 1H-tetrazole, 5-amino-1H-tetrazole, 5-methyl-1H-tetrazole, 5-phenyl-1H-tetrazole, 1-(2-diaminoethyl)-5-mercaptotetrazole, and the like.

Specific examples of the pyrazole ring-containing compound may include 3,5-dimethylpyrazole, 3-amino-5-methylpyrazole, 4-methylpyrazole, 3-amino-5-hydroxypyrazole, and the like.

Specific examples of the purine ring-containing compound may include purine and the like.

Specific examples of the mercapto group-containing compound may include 1-thioglycerol, 3-(2-aminophenylthio)-2-hydroxypropyl mercaptan, 3-(2-hydroxyethylthio)-2-hydroxypropyl mercaptan, 2-mercaptopropionic acid, 3-mercaptopropionic acid, and the like.

Specific examples of the aliphatic amine compound may include an alkylamine, a dialkylamine, a trialkylamine, and the like.

Specific examples of the zwitterionic compound may include a compound containing a cationic moiety such as a tertiary amine, a quaternary amine, etc., and an anionic moiety such as a sulfonic acid group, a carboxyl group, etc. Examples thereof may include a zwitterionic compound represented by R₃N⁺—CHR′—SO₃⁻, etc. (R represents a monovalent hydrocarbon group, and R′ represents a divalent hydrocarbon group), a zwitterionic compound represented by R₃N⁺—CHR′—COO⁻, etc. (R represents a monovalent hydrocarbon group, and R′ represents a divalent hydrocarbon group), and the like. Further, for example, carbobetaine, sulfobetaine, and the like can be used as the zwitterionic compound.

The anticorrosive agent may also be a salt of the compounds described above. Specific examples of the salt may include, but are not particularly limited to, a sodium salt, a potassium salt, an ammonium salt, an alkylammonium salt (for example, a tetramethylammonium salt, etc.), and the like. It may also be a hydrate of the above compounds.

Furthermore, a preferred example of the anticorrosive agent from another viewpoint may for example be at least one selected from the group consisting of a 5-membered ring-containing compound (a), a 6-membered ring-containing compound (b), a fused ring-containing compound (c), an alkylammonium salt (d), a heterocyclic ring-containing alkylammonium salt (e), and a zwitterionic compound (f). The cleaning solution according to the present embodiment preferably includes one selected from the group.

As the 5-membered ring-containing compound (a), a nitrogen-containing 5-membered ring-containing compound is preferable. As specific examples of the 5-membered ring-containing compound, compounds having the following structures (compound (al) to compound (a8)) are preferable.

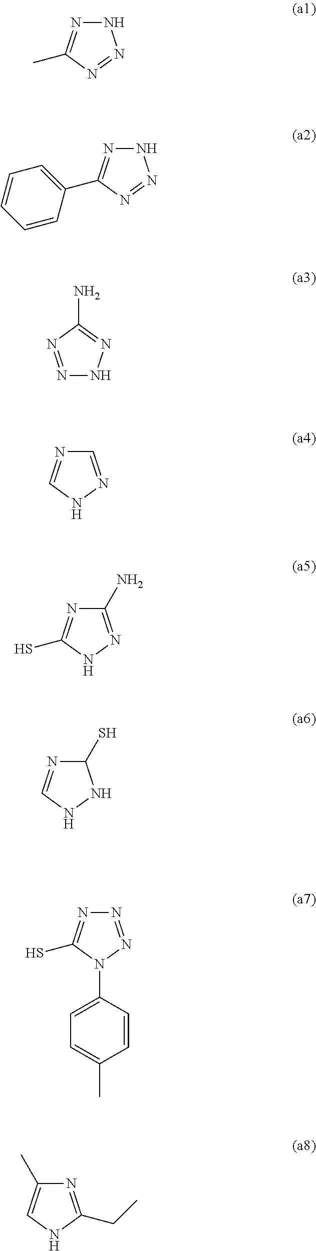

As the 6-membered ring-containing compound (b), a nitrogen-containing 6-membered ring-containing compound is preferable. As specific examples of the 6-membered ring-containing compound, compounds having the following structures (compound (b1) to compound (b6)) are preferable.

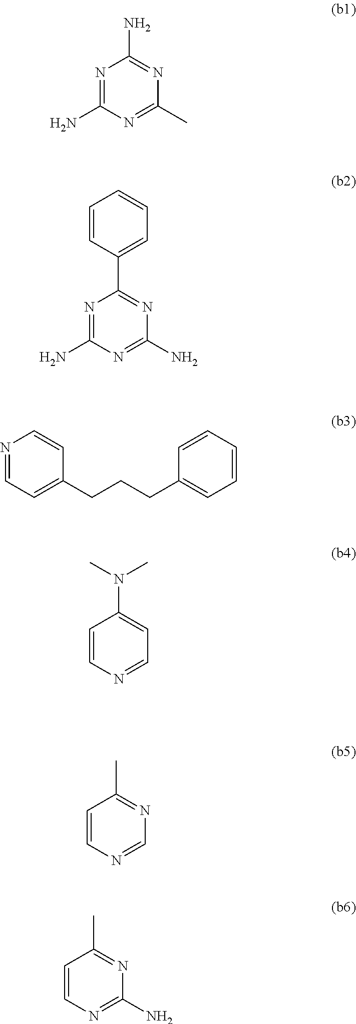

As the fused ring-containing compound (c), a nitrogen-containing fused ring-containing compound is preferable. As specific examples of the fused ring-containing compound, compounds having the following structures (compound (c1) to compound (c5)) are preferable.

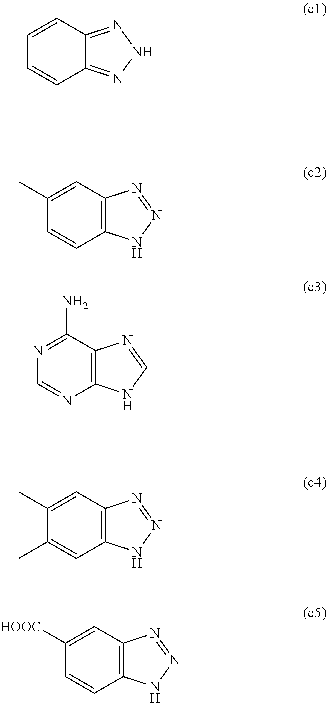

As the alkylammonium salt (d), compounds having the following structures (compound (d1) to compound (d6)) are preferable. Note that the following alkylammonium salts are each an alkylammonium salt that does not contain a heterocyclic ring.

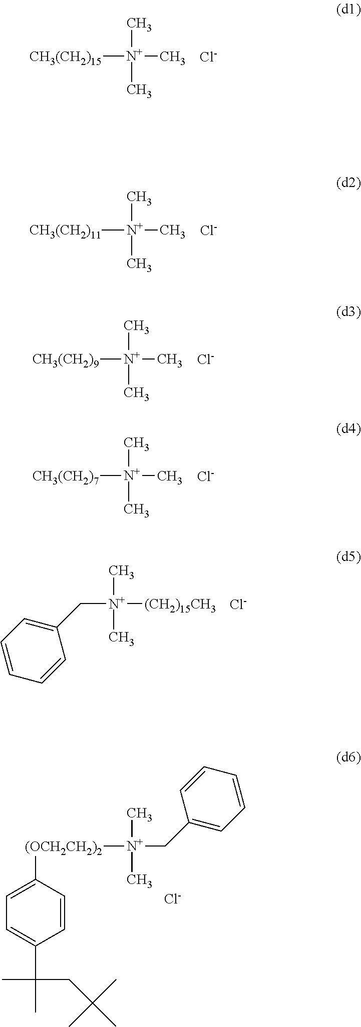

As the heterocyclic ring-containing alkylammonium salt (e), compounds having the following structures (compound (e1) to compound (e3)) are preferable.

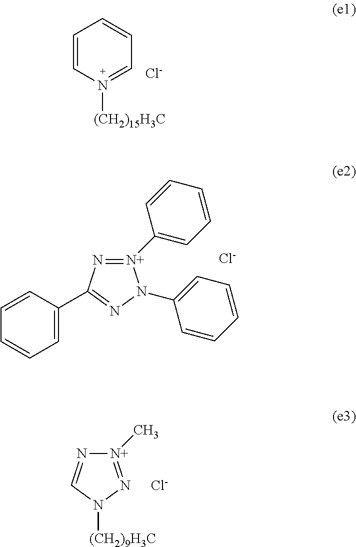

As the zwitterionic compound (f), compounds having the following structures (compound (f1) to compound (f3)) are preferable.

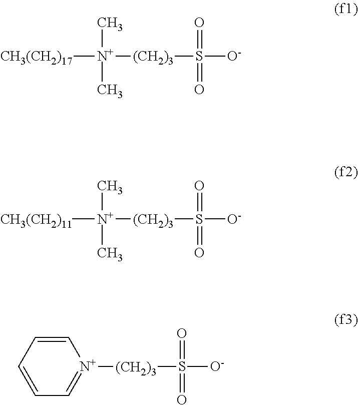

The anticorrosive agent may also be a salt of the compounds described above. Specific examples of the salt may include, but are not particularly limited to, a sodium salt, a potassium salt, an ammonium salt, an alkylammonium salt (for example, a tetramethylammonium salt, etc.), and the like. It may also be a hydrate of the above compounds.

The concentration of the anticorrosive agent in the cleaning solution according to the present embodiment is preferably from 0.0001 to 10% by mass. The upper limit of the concentration of the anticorrosive agent is more preferably 5% by mass or less, and even more preferably 1% by mass or less. The lower limit of the concentration of the anticorrosive agent is more preferably 0.001% by mass or more, and even more preferably 0.01% by mass or more.

### (Buffer)

The cleaning solution according to the present embodiment may contain a buffer. A buffer is a compound that has a mechanism of inhibiting a change in the pH of a cleaning solution. By containing a buffer, the cleaning solution can be efficiently controlled such that the pH value of the cleaning solution is smaller than the acid dissociation constant. In addition, by containing a buffering agent, the cleaning solution can be efficiently controlled such that the pH of the cleaning solution is at a predetermined value. The buffer is not particularly limited as long as it is a compound having pH buffering ability.

Examples of the buffer may include Good's buffer. Examples of Good's buffer may include 2-cyclohexylaminoethanesulfonic acid (CHES), 3-cyclohexylaminopropanesulfonic acid (CAPS), N-tris(hydroxymethyl)methyl-3-aminopropanesulfonic acid (TAPS), 4-(cyclohexylamino)-1-butanesulfonic acid (CABS), tricine, bicine, 2-morpholinoethanesulfonic acid monohydrate (MES), bis(2-hydroxyethyl)aminotris(hydroxymethyl) methane (Bis-Tris), N-(2-acetamido)iminodiacetic acid (ADA), piperazine-1,4-bis(2-ethanesulfonic acid) (PIPES), N-(2-acetamido)-2-aminoethanesulfonic acid (ACES), 2-hydroxy-3-morpholinopropanesulfonic acid (MOPSO), N,N-bis(2-hydroxyethyl)-2-aminoethanesulfonic acid (BES), 3-morpholinopropanesulfonic acid (MOPS), N-tris(hydroxymethyl)methyl-2-aminoethanesulfonic acid (TES), 2-[4-(2-hydroxyethyl)-1-piperazinyl]ethanesulfonic acid (HEPES), 3-[N-tris(hydroxymethyl)methylamino]-2-hydroxypropanesulfonic acid (TAPSO), piperazine-1,4-bis(2-hydroxypropanesulfonic acid) (POPSO), 4-(2-hydroxyethyl)piperazine-1-(2-hydroxypropane-3-sulfonic acid) (HEPSO), 4-(2-hydroxyethyl)-1-piperazinepropanesulfonic acid (EPPS), and the like.

The buffer may be used alone or in combination of two or more. Alternatively, the cleaning solution according to the present embodiment may not contain a buffer.

### (Surfactant)

The cleaning solution according to the present embodiment may contain a surfactant for the purpose of adjusting wettability of the cleaning solution to a substrate; and the like. Examples of the surfactant may include a nonionic surfactant, an anionic surfactant, a cationic surfactant, an amphoteric surfactant, etc.

Examples of the nonionic surfactant may include a polyalkylene oxide alkyl phenyl ether-based surfactant, a polyalkylene oxide alkyl ether-based surfactant, a block polymer-based surfactant composed of polyethylene oxide and polypropylene oxide, a polyoxyalkylene distyrenated phenyl ether-based surfactant, a polyalkylene tribenzyl phenyl ether-based surfactant, an acetylene polyalkylene oxide-based surfactant, and the like.

Examples of the anionic surfactant may include alkyl sulfonic acid, alkyl benzene sulfonic acid, alkyl naphthalene sulfonic acid, alkyl diphenyl ether sulfonic acid, fatty acid amide sulfonic acid, polyoxyethylene alkyl ether carboxylic acid, polyoxyethylene alkyl ether acetic acid, polyoxyethylene alkyl ether propionic acid, alkyl phosphonic acid, fatty acid, a salt thereof, and the like. Examples of the salt may include, but are not particularly limited to, a sodium salt, a potassium salt, an ammonium salt, an alkylammonium salt (e.g., a tetramethylammonium salt, etc.), and the like.

Examples of the cationic surfactant may include an alkylpyridium-based surfactant, a quaternary ammonium salt-based surfactant, and the like.

Examples of the amphoteric surfactant may include a betaine-type surfactant, an amino acid-type surfactant, an imidazoline-type surfactant, an amine oxide-type surfactant, and the like.

These surfactants are generally commercially available. These surfactants may be used alone or in combination of two or more.

When the cleaning solution according to the present embodiment contains a surfactant, the content of the surfactant is not particularly limited and is preferably from 0.0001% by mass to 5% by mass with respect to the total mass of the cleaning solution, for example. The lower limit of the content thereof is more preferably 0.0002% by mass or more, and even more preferably 0.002% by mass or more. The upper limit of the content thereof is more preferably 3% by mass or less, even more preferably 1% by mass or less, and still even more preferably 0.2% by mass or less.

The cleaning solution according to the present embodiment may not contain one or more kinds of surfactant selected from the group consisting of the nonionic surfactant, the anionic surfactant, the cationic surfactant, and the amphoteric surfactant, and may not contain one or more of the above compounds exemplified as these surfactants. The cleaning solution according to the present embodiment may not contain a surfactant.

### (pH Adjuster)

The cleaning solution according to the present embodiment may contain a pH adjuster in order to adjust to a desired pH. As the pH adjuster, an inorganic acid, an organic acid, an organic basic compound, and an inorganic basic compound can be appropriately used.

### (Impurity, etc.)

The cleaning solution according to the present embodiment may contain a metal impurity containing at least one metal atom selected from the group consisting of a Fe atom, a Cr atom, a Ni atom, a Zn atom, a Ca atom, a Pb atom, etc., for example.

The total content of the metal atom in the cleaning solution according to the present embodiment is preferably 100 ppt by mass or less with respect to the total mass of the cleaning solution. The lower the lower limit of the total content of the metal atom, the more preferable it is. For example, the lower limit may be 0.001 ppt by mass or more. The total content of the metal atom may for example be from 0.001 ppt by mass to 100 ppt by mass. It is considered that the total content of the metal atom equal to or lower than the above preferred upper limit improves defect suppression properties and residue suppression properties of the cleaning solution. It is considered that, with the total content of the metal atom equal to or higher than the above preferred lower limit, the metal atom is less likely to be a free atom in the system and less likely to have a negative impact on the production yield of an entire object to be cleaned.

The content of the metal impurity can be adjusted by, for example, a purification process such as filtering, etc. The purification process such as filtering, etc. may be performed on a part or all of the raw materials before preparation of the cleaning solution, or may be performed after preparation of the cleaning solution.

The cleaning solution according to the present embodiment may contain, for example, an impurity derived from an organic substance (organic impurity). The total content of the above organic impurity in the cleaning solution according to the present embodiment is preferably 5000 ppm by mass or less. The lower the lower limit of the total content of the organic impurity, the more preferable it is. For example, the lower limit may be 0.1 ppm by mass or more. Examples of the total content of the organic impurity may include from 0.1 ppm by mass to 5000 ppm by mass.

The cleaning solution according to the present embodiment may contain an object to be counted of such a size as counted by a light scattering liquid-borne particle counter, for example. The size of the object to be counted is, for example, 0.04 μm or more. The number of the object to be counted contained in the cleaning solution according to the present embodiment is, for example, 1,000 or less per 1 mL of the cleaning solution, and the lower limit thereof is, for example, 1 or more. It is considered that the number of the object to be counted in the cleaning solution within the above-described range improves a metal corrosion suppression effect of the cleaning solution.

The organic impurity and/or the object to be counted may be added to the cleaning solution or may be inevitably mixed in the cleaning solution in the manufacturing process of the cleaning solution. As non-limiting examples of the case that the organic impurity and/or the object to be counted is inevitably mixed in the cleaning solution in the manufacturing process of the cleaning solution, the organic impurity may be contained in a raw material (for example, an organic solvent) used for manufacturing the cleaning solution, or may be mixed in from an external environment in the manufacturing process of the cleaning solution (for example, contamination).

In the case that the object to be counted is added to the cleaning solution, the presence ratio may be adjusted for each specific size in consideration of surface roughness of an object to be cleaned, and the like.

### (Solvent)

The cleaning solution according to the present embodiment may contain a solvent. As the solvent, it preferably contains water, for example. The cleaning solution according to the present embodiment can be suitably used as an aqueous cleaning solution.

The content of the water in the cleaning solution according to the present embodiment is not particularly limited, but is preferably from 1 to 99% by mass. From the viewpoint that the residue removal properties and anti-corrosion properties can be maintained at high levels while imparting water solubility as an aqueous cleaning solution, the lower limit of the content thereof is more preferably 25% by mass or more, even more preferably 35% by mass or more, still even more preferably 45% by mass or more, still even more preferably 50% by mass or more, still even more preferably 55% by mass or more, still even more preferably 60% by mass or more, still even more preferably 80% by mass or more, and still even more preferably 90% by mass or more. In addition, from the viewpoint that the residue removal properties and anti-corrosion properties can be maintained at high levels while imparting water solubility as an aqueous cleaning solution, the upper limit of the content thereof is more preferably 98% by mass or less, and even more preferably 97% by mass or less. With the water content within the range described above, another component can be dissolved uniformly and stably.

The cleaning solution according to the present embodiment may contain an organic solvent. Specific examples of the organic solvent may include, but are not particularly limited to, at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent. Furthermore, it is preferable the cleaning solution according to the present embodiment contain only at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent, and do not contain a solvent other than these. Further, when the cleaning solution according to the present embodiment contains an organic solvent, it is preferable to use a water-soluble organic solvent from the viewpoint of water solubility of the cleaning solution.

Specific examples of the alcohol-based solvent may include aliphatic alcohols such as methanol, ethanol, modified ethanol, isopropanol, n-propanol, n-butanol, 3-methoxy-3-methyl-1-butanol, etc.; glycols such as ethylene glycol (also known as 1,2-ethanediol, monoethylene glycol), diethylene glycol (also known as 2,2′-oxydiethanol, diethyl glycol), propylene glycol (also known as propane-1,2-diol), dipropylene glycol, glycerin, 1,3-propanediol, 1,3-butanediol, 1,4-butanediol, furfuryl alcohol, hexylene glycol (also known as 2-methyl-2,4-pentanediol), etc.; and the like.

Specific examples of the glycol ester-based solvent may include ethylene-based glycol ether such as ethylene glycol monomethyl ether, ethylene glycol dimethyl ether, diethylene glycol monomethyl ether, diethylene glycol dimethyl ether, triethylene glycol monomethyl ether, triethylene glycol dimethyl ether, ethylene glycol monoethyl ether, ethylene glycol diethyl ether, ethylene glycol monobutyl ether, ethylene glycol dibutyl ether, diethylene glycol monobutyl ether, diethylene glycol dibutyl ether, triethylene glycol monobutyl ether, triethylene glycol dibutyl ether, ethylene glycol monohexyl ether, ethylene glycol dihexyl ether, diethylene glycol monohexyl ether, diethylene glycol dihexyl ether, ethylene glycol-phenyl ether, etc.; ethylene-based glycol ether acetates such as ethylene glycol monobutyl ether acetate, diethylene glycol monobutyl ether acetate, etc.; propylene-based glycol ether such as propylene glycol monomethyl ether (PGME), propylene glycol dimethyl ether, dipropylene glycol monomethyl ether (DPM), dipropylene glycol dimethyl ether, tripropylene glycol monomethyl ether, tripropylene glycol dimethyl ether, propylene glycol monoethyl ether, propylene glycol diethyl ether, dipropylene glycol monoethyl ether, dipropylene glycol diethyl ether, tripropylene glycol monoethyl ether, tripropylene glycol diethyl ether, propylene glycol monopropyl ether, propylene glycol dipropyl ether, dipropylene glycol monopropyl ether, dipropylene glycol dipropyl ether, propylene glycol monobutyl ether, propylene glycol dibutyl ether, dipropylene glycol monobutyl ether, dipropylene glycol dibutyl ether, tripropylene glycol monobutyl ether, tripropylene glycol dibutyl ether, propylene glycol phenyl ether, etc.; propylene-based glycol ether acetates such as propylene glycol methyl ether acetate, dipropylene glycol methyl ether acetate, propylene glycol diacetate, etc.; and the like.

Specific examples of the sulfoxide-based solvent may include dimethyl sulfoxide (DMSO), diethyl sulfoxide, dipropyl sulfoxide, diphenyl sulfoxide, thiophene, and the like.

Specific examples of the sulfone-based solvent may include dimethyl sulfone, diethyl sulfone, tetramethylene sulfone, dipropyl sulfone, sulfolane (also known as tetramethylene sulfone), 3-methylsulfolane, 2,4-dimethylsulfolane, 3,4-dimethylsulfolane, diphenylsulfolane, 3,4-diphenylmethylsulfolane, sulfolene, 3-methylsulfolene, 3-ethylsulfolene, and the like.

Specific examples of the amide-based solvent may include dimethylformamide (DMF), diethylformamide (DEF), dimethylacetamide (DMAc), N-methylpyrrolidine (MPD), hexamethylphosphate triamide (HMPA), and the like.

Specific examples of the lactone-based solvent may include γ-butyllactone, α-methyl-γ-butyrolactone, β-propiolactone, γ-valerolactone, δ-valerolactone, γ-caprolactone, ε-caprolactone, γ-laurolactone, hexanolactone, and the like.

Specific examples of the imidazolidinone-based solvent may include 2-imidazolidinone, 1,3-dimethyl-2-imidazolidinone, 1,3-diethyl-2-imidazolidinone, 1,3-dipropyl-2-imidazolidinone, 1,3-diisopropyl-2-imidazolidinone, and the like.

Specific examples of the nitrile-based solvent may include acetonitrile, propionitrile, valeronitrile, butyronitrile, and the like.

Specific examples of the ketone-based solvent may include acetone, methyl ethyl ketone (MEK), methyl isobutyl ketone (MIBK), diisobutyl ketone, cyclohexanone, diacetone alcohol, 1-hexanone, 2-hexanone, 4-heptanone, 2-heptanone (methylamyl ketone), 1-octanone, 2-octanone, 1-nonanone, 2-nonanone, acetylacetone, acetonyl acetone, phenylacetone, acetophenone, methylnaphthyl ketone, methylcyclohexanone, ionone, isophorone, propylene carbonate, diacetonyl alcohol, acetylcarbinol, and the like.

Specific examples of the ether-based solvent may include diisopropyl ether, 1,4-dioxane, methyl-tert-butyl ether (MTBE), dimethyl ether, diethyl ether, dipropyl ether, methylphenyl ether, and the like.

Specific examples of the ester-based solvent may include methyl acetate, ethyl acetate, butyl acetate, amyl acetate, propyl acetate, isopropyl acetate, methyl lactate, ethyl methoxyacetate, ethyl ethoxyacetate, acetic acid 2-methoxybutyl (2-methoxybutyl acetate), acetic acid 3-methoxybutyl (3-methoxybutyl acetate), acetic acid 4-methoxybutyl (4-methoxybutyl acetate), acetic acid 3-methoxy-3-methylbutyl (3-methoxy-3-methylbutyl acetate), acetic acid 3-ethyl-3-methylbutyl (3-ethyl-3-methoxybutyl acetate), 4-methyl-4-methoxypentyl acetate, methyl formate, ethyl formate, propyl formate, butyl formate, ethyl lactate (EL), propyl lactate, butyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, and the like.

Specific examples of the pyrrolidone-based solvent may include N-methylpyrrolidone (NMP), 2-pyrrolidone, N-vinyl-2-pyrrolidone, and the like.

Specific examples of the urea-based solvent may include 1,3-dimethylurea, 1,3-diethylurea, 1,3-dipropylurea, 1,3-diisopropylurea, tetramethylurea, tetraethylurea, tetrapropylurea, tetraisopropylurea, N, N-dimethylpropylene urea, and the like.

Among the above, the organic solvent is preferably a water-soluble organic solvent. Among the above specific examples, preferred examples of the water-soluble organic solvent may include alcohols such as isopropanol, ethanol, ethylene glycol, propylene glycol, glycerin, 1,3-propanediol, 1,3-butanediol, 1,4-butanediol, diethylene glycol, dipropylene glycol, furfuryl alcohol, hexylene glycol (also known as 2-methyl-2,4-pentanediol), etc.; glycol ester-based solvents such as diethylene glycol monobutyl ether, propylene glycol monomethyl ether, etc.; dimethyl sulfoxide; ethers such as ethylene glycol dimethyl ether, diethylene glycol dimethyl ether, triethylene glycol dimethyl ether, tetraethylene glycol dimethyl ether, propylene glycol dimethyl ether, etc.; morpholins such as N-methylmorpholine N-oxide, etc.; and the like. Among them, more preferred examples thereof may include hexylene glycol (also known as 2-methyl-2,4-pentanediol) and the like.

By using such a preferred solvent, for example, the anti-corrosion properties of a layer containing a metal component such as cobalt, copper, tungsten, ruthenium, aluminum, molybdenum, etc. as a main component (for example, the metal wiring layer 20, the etching stop layer 30, the interlayer insulating film 40, another functional layer, etc.) can be further improved. That is, when such a solvent is used, damage (film loss) caused to the layer containing cobalt, etc. can be more effectively reduced without impairing removability of a titanium-based residue.

The organic solvent may be used alone or in combination of two or more.

Furthermore, it is expected that the cleaning solution according to the present embodiment can achieve a desired effect even if a halogenated solvent is not used. That is, the cleaning solution according to the present embodiment can be used as an environment-friendly and halogen-free cleaning solution. From such a viewpoint, preferred examples of the cleaning solution according to the present embodiment may include a cleaning solution that does not substantially contain a halogen atom, and even a cleaning solution that does not contain a halogen atom. In particular, when the cleaning solution does not substantially contain a fluorine atom such as fluoride, etc., it can be expected that damage to silicon compounds such as SiN, SiO₂, ILD, an interlayer insulating film, etc. can be more effectively suppressed. Note that “does not substantially contain” means a case where the component is inevitably blended as an impurity is not excluded. For example, the content of the component in the cleaning solution is preferably 1% by mass or less, more preferably 0.5% by mass or less, even more preferably 0.3% by mass or less, still even more preferably 0.1% by mass or less, and further more preferably 0% by mass.

Although the cleaning solution according to the present embodiment can be expected to have a sufficient effect even if it does not contain an organic solvent, it can be expected to have a sufficient effect even if it contains an organic solvent. That is, the cleaning solution according to the present embodiment may contain an organic solvent. From such viewpoints, the content of the organic solvent in the present embodiment can be from 0 to 95% by mass. The lower limit of the content of the organic solvent in the cleaning solution may be 0% by mass; or may be, for example, 5% by mass or more, 10% by mass or more, 20% by mass or more, 30% by mass or more, 40% by mass or more, 50% by mass or more, or 60% by mass or more, depending on a component of the cleaning solution, etc. The upper limit of the content of the organic solvent in the cleaning solution may be, for example, 90% by mass or less, 80% by mass or less, or 70% by mass or less.

When the cleaning solution according to the present embodiment contains water and an organic solvent, the content ratio of the organic solvent is preferably from 0.05 to 50% by mass with respect to the total amount of the water and organic solvent. The lower limit of the content ratio may be, for example, 0.1% by mass or more. Further, the upper limit of the content ratio is more preferably 30% by mass or less, even more preferably 20% by mass or less, and still even more preferably 10% by mass or less. When the cleaning solution according to the present embodiment contains water and an organic solvent, by setting to the content ratio as described above, the solvent can be a water-soluble mixed solvent, which is preferable in that higher water solubility can be imparted to the cleaning solution.

Although the cleaning solution according to the present embodiment may not contain an organic solvent, a sufficient effect thereof can be obtained even when an organic solvent is used in combination with water. When an organic solvent and water are used in combination, from the viewpoint of imparting water solubility as an aqueous cleaning solution, a combination of alcohol and water is preferable, a combination of glycols and water is more preferable, and a combination of hexylene glycol and water is even more preferable.

The cleaning solution according to the present embodiment can be used for various purposes. Among them, from the viewpoint that the effect and advantage of the present embodiment can be effectively utilized, the cleaning solution according to the present embodiment is suitable for cleaning a semiconductor substrate on which a film containing titanium or a titanium-based alloy is formed. More specifically, a preferred example of the present embodiment is a cleaning solution for a semiconductor substrate, where the semiconductor substrate includes a substrate and a film formed on the substrate, and the film contains titanium or a titanium-based alloy.

Here, an exemplary semiconductor substrate to which the cleaning solution according to the present embodiment can be used will be described.

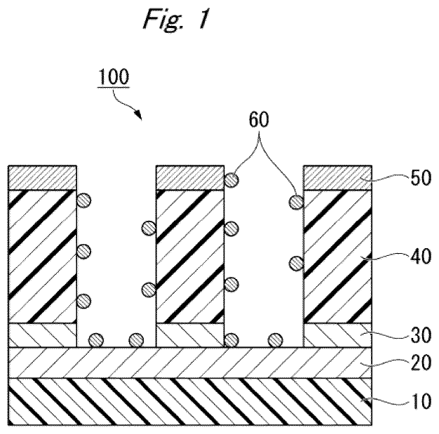

FIG. 1 is a cross-sectional view illustrating an exemplary element (semiconductor substrate) to be cleaned after dry etching.

A semiconductor device 100 illustrated in FIG. 1 includes a substrate 10, a metal wiring layer 20, an etching stop layer 30, and an interlayer insulating film 40, which are laminated in this order, and a hard mask layer (HM layer) 50 is formed on the interlayer insulating film 40 (substrate 10/metal wiring layer 20/etching stop layer 30/interlayer insulating film 40/HM layer 50).

The semiconductor element 100 has been subjected to dry etching in a wiring process. That is, the semiconductor is in a state after the dry-etching of the interlayer insulating film 40 by using as a mask the HM layer 50 having a basic shape of a wiring pattern formed by dry etching. Dry etching residues 60 are adhered to side surfaces of the HM layer 50 and the interlayer insulating film 40. Although a case where etching is performed by dry etching is described here as an example, when etching is performed by wet etching, the resultant residue is a wet etching residue.

The metal wiring layer 20 is exposed to spaces in the interlayer insulating film 40 in the shape of the wiring pattern, and the dry etching residues 60 are also adhered.

As the substrate 10, for example, a substrate made of a material such as silicon, amorphous silicon, glass, or the like can be used.

The metal wiring layer 20 is a wiring layer containing one of metals such as molybdenum (Mo), tungsten (W), ruthenium (Ru), copper (Cu), iron (Fe), gold (Au), silver (Ag), nickel (Ni), aluminum (Al), lead (Pb), zinc (Zn), tin (Sn), tantalum (Ta), magnesium (Mg), cobalt (Co), bismuth (Bi), cadmium (Cd), titanium (Ti), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), thallium (Tl), etc. and a metal oxide, a metal nitride, a metal chloride, a metal fluoride, etc. thereof.

Note that the metal wiring layer 20 is not limited to wiring and broadly includes those functioning as a functional layer such as an electrode, an insulating layer, a low dielectric layer, and various conductor layers. It includes a layer formed by using the metals mentioned above and a metal oxide, a metal nitride, a metal chloride, a metal fluoride, etc. thereof. For example, in the case of a silicon-based metal wiring layer, a SiN, SiOz, or Low-k film (SiOC film, SiCOH film, etc.), ILD, and the like can be exemplified.

A material of the interlayer insulating film 40 may be any material as long as it has insulating properties. The material is not particularly limited, and a suitable material may be appropriately selected in consideration of a manufacturing condition and the like. As the interlayer insulating film 40, for example, a layer containing a silicon-based material such as SiO₂, SiN, SiOc, SiOCN, etc. can be used.

A material of the HM layer 50 may be any material as long as it acts as a protective film against etching. The material is not particularly limited, and a suitable material may be appropriately selected in consideration of a manufacturing condition and the like. As the HM layer 50, for example, a layer containing titanium and/or a titanium-based alloy can be suitably used. Since the cleaning solution according to the present embodiment is at least excellent in removability of a titanium-based residue, a residue generated from the HM layer using such a material (refer to the dry etching residue 60) can be efficiently removed. As described above, as a titanium-based alloy, a titanium-based material such as titanium nitride (TiN), titanium oxide (TiOₓ (x represents a number.)), titanium oxynitride (TiON), titanium oxyfluoride (TiOF), etc. can be used.

The dry etching residue 60 is mainly a Ti-containing residue including a titanium-based material derived from the HM layer 50, but is not limited to such a residue. The dry etching residue 60 includes, for example, an etching residue containing the above-described inorganic substance, and the like.

### <Cleaning Method>

The cleaning solution according to the present embodiment can be suitably used as a method for cleaning a semiconductor substrate. A method for cleaning a semiconductor substrate according to the present embodiment is a method for cleaning a semiconductor substrate having a protective film, and is a method for cleaning a semiconductor substrate that includes a step of removing an impurity from the semiconductor substrate by bringing the above-mentioned cleaning solution into contact with the protective film. For example, in the case of the semiconductor element 100 (semiconductor substrate) illustrated in FIG. 1, the HM layer 50 corresponds to the protective film. Hereinafter, a case of cleaning the semiconductor element 100 illustrated in FIG. 1 will be described as an example.

The method for cleaning the semiconductor substrate according to the present embodiment is a step of cleaning the semiconductor element 100 after dry etching is performed in a wiring process, using the cleaning solution described above. A method for implementing the cleaning is not particularly limited, and a known cleaning method can be used.

When bringing the cleaning solution into contact with the semiconductor element 100 to be cleaned, the cleaning solution may be diluted 2 to 2000 times to obtain a diluted solution, and a cleaning operation may then be performed using the diluted solution.

Examples of the cleaning operation may include a method of continuously discharging the cleaning solution on the semiconductor element 100 rotating at a constant speed (rotational application method), a method of immersing the semiconductor element 100 in the cleaning solution for a certain period of time (dipping method), a method of spraying the cleaning solution on a surface of the semiconductor element 100 (spraying method), and the like.

A temperature at which a cleaning processing is performed is not particularly limited, but the cleaning processing is preferably performed under the condition of 10 to 80° C. The lower limit of the temperature of the cleaning processing (the temperature of the cleaning solution) is more preferably 20° C. or more, and even more preferably 40° C. or more. The upper limit of the temperature of the cleaning processing (the temperature of the cleaning solution) is more preferably 75° C. or less, and even more preferably 70° C. or less. With the lower limit of the temperature of the cleaning processing within the range described above, the removability of an etching residue can be further improved. With the upper limit of the temperature of the cleaning processing within the range described above, it is possible to more effectively suppress an unintentional change in the composition of the cleaning solution, and it is possible to clean more efficiently from the viewpoint of workability, safety, cost, and the like.

Cleaning time can be appropriately selected so as to be sufficient for removing an etching residue, an impurity, and the like adhered on a surface of the semiconductor element 100. For example, the cleaning time is preferably from 10 seconds to 30 minutes. The lower limit of the cleaning time is more preferably 20 seconds or more, and even more preferably 30 seconds or more. The upper limit of the cleaning time is more preferably 15 minutes or less, even more preferably 10 minutes or less, and still even more preferably 5 minutes or less.

Since the cleaning solution according to the present embodiment is used for cleaning, in the semiconductor element 100 to which the dry etching residues 60 are adhered, the dry etching residues 60 derived from the HM layer 50, which is a protective film, can be well cleaned and removed while damage to the metal wiring layer 20 is suppressed. In particular, in the case of a HM layer containing titanium and/or a titanium alloy, the cleaning solution according to the present embodiment is particularly suitable since it is excellent in removability of a titanium-based residue.

In addition, by using the cleaning solution according to the present embodiment, damage to various functional layers (metal wiring layer 20, etching stop layer 30, interlayer insulating film 40, etc.) other than the protective film can be suppressed.

Furthermore, since the cleaning solution according to the present embodiment can obtain a cleaning effect of an extend that a semiconductor element is practicable without using a conventional general-purpose hydroxylamine or the like, it can be expected that an semiconductor element, etc. can be manufactured more safely.

### <Method for Manufacturing a Semiconductor>

The cleaning solution according to the present embodiment and the cleaning method using the same can be suitably used as a method for manufacturing a semiconductor. A method for manufacturing a semiconductor according to the present embodiment is a method for manufacturing a semiconductor that includes, for example, (1) a step of preparing a substrate having a protective film, (2) a step of etching the protective film, and (3) a step of removing an impurity from the substrate by bringing the above cleaning solution into contact with the substrate, after the etching. For example, in the case of the semiconductor element 100 (semiconductor substrate) illustrated in FIG. 1, the HM layer 50 corresponds to the protective film, as in the description of the cleaning method. Hereinafter, a case of cleaning the semiconductor element 100 illustrated in FIG. 1 will be described as an example.

### (1) Step of Preparing a Substrate Having a Protective Film

In step (1), a substrate having at least a protective film is prepared. Although not illustrated, in the case of FIG. 1, a laminate before etching that has in this order a substrate 10, a metal wiring layer 20, an etching stop layer 30, an interlayer insulating film 40, and a hard mask layer (HM layer) 50 corresponding to the protective film is prepared (substrate 10/metal wiring layer 20/etching stop layer 30/interlayer insulating film 40/HM layer 50).

A method for sequentially laminating the substrate 10, the metal wiring layer 20, the etching stop layer 30, the interlayer insulating film 40, and the hard mask layer (HM layer) 50 corresponding to the protective film, on the substrate 10 is not particularly limited, and a known method can be employed.

### (2) Step of Etching the Protective Film

Subsequently, the protective film is subject to etching. An etching method is not particularly limited, may be wet etching or dry etching, but is preferably dry etching. Dry etching is advantageous from the viewpoint that a metal wiring at nano level is possible, and gas used can be controlled. In the case of dry etching, there is a concern that damage to the substrate, etc. is relatively large, but from the viewpoint that such damage can be effectively suppressed by using the cleaning solution according to the present embodiment, dry etching is also desirable in a point that the advantage of the present embodiment can be more effectively reflected.

In the case of dry etching, plasma can be used. Usually, when plasma etching is performed, there is a problem that the substrate is easily damaged, or a problem that plasma etching generates a plasma etching residue and it is necessary to clean it with a cleaning solution. However, dry etching is also preferable in a point that such problems can be effectively suppressed by using the cleaning solution according to the present embodiment.

(3) Step of Removing an Impurity from the Substrate by Bringing the Above Cleaning Solution into Contact with the Substrate, after Etching

As the step (3), the cleaning methods described above can be used. Thereby, the semiconductor element 100 can be obtained. As necessary, a known post-processing can be performed after the cleaning.

As described above, the cleaning solution according to the present embodiment can be used, for example, as a cleaning solution for removing a residue generated in a semiconductor etching step, etc., and in particular, the cleaning solution according to the present embodiment is suitable for removing a residue generated by dry etching. The cleaning solution according to the present embodiment has an advantage that it can efficiently remove a titanium-based residue and has excellent anti-corrosion properties. Therefore, it can remove a residue generated when a substrate having a hard mask layer (HM layer) mainly composed of titanium or a titanium alloy is dry etched more efficiently as compared with conventional ones.

When a cleaning solution containing hydroxylamine, a cleaning solution containing hydrogen fluoride, and a cleaning solution containing hydrogen peroxide, etc. that have been conventionally used are used, there may be a problem such as large damage to a film (that is, a large amount of film loss). However, since the cleaning solution according to the present embodiment has excellent anti-corrosion properties, the occurrence of such a defect can be effectively suppressed. For example, the cleaning solution according to the present embodiment is suitable because it can be expected to reduce damage to a substrate, a metal wiring, an etching stop layer, an interlayer insulating film and various other functional layers which contain a silicon compound such as Si, SiN, etc. or a metal component such as tungsten, molybdenum, cobalt, etc. Therefore, the cleaning solution according to the present embodiment can be sufficiently a cleaning solution particularly excellent in removability of a titanium-based residue and in anti-corrosion properties for highly versatile materials such as a silicon compound and metal materials such as tungsten, molybdenum, cobalt, etc.

Furthermore, since the cleaning solution according to the present embodiment can be a halogen-free cleaning solution, not only is it environmentally friendly, but it can also be used easily in terms of ease of disposal. In particular, when fluoride is not used, it can be expected that damage to a material using a silicon compound such as Si, SiN, etc. can be more effectively suppressed.

### EXAMPLES

The present invention will be described in more detail with reference to the following Examples and Comparative examples, but the present invention is not limited in any way to the following examples.

### 1. Test 1

### 1-1. Preparation of Cleaning Solution

### Example 1

A cleaning solution was obtained by blending oxalic acid ((COOH)₂) and water in the proportions shown in Table 2. Example 1 is a cleaning solution containing only 3% by mass of oxalic acid as a cleaning agent and 97% by mass of water.

### Examples 2, 3, Comparative Examples 1 to 3

Cleaning solutions were obtained in the same manner as in Example 1 except that the cleaning agent and water were blended at the proportions shown in Table 2. For example, Example 2 is a cleaning solution containing 10% by mass of phosphoric acid and 90% by mass of water.

### <pKa of Oxoacid>

The pKa of oxo acid (for example, oxalic acid in Example 1) contained in each cleaning solution was determined based on “Sparc Calculator” (archemcalc.com) operated by Archem Inc. on the Internet. (Reference: URL: http://archemcalc.com/sparc-web/calc#/multiproperty)

### <Measuring Method of the pH of Cleaning Solution>

The pH of each cleaning solution was measured using a pH/ORP meter (portable pH meter “ORION STAR A324”, manufactured by Thermo Scientific) under a temperature condition of 22° C.

### 1-2. Evaluation of Removability of Titanium-Based Residue (Residue Removal Properties)

The residue removal properties of Examples and Comparative examples were evaluated by the following method.

First, a laminate (a substrate having a film) was prepared by a CVD method, in which a third layer (a metal wiring layer, cobalt), an etching stop layer (aluminum oxide), a second layer (an interlayer insulating film), and a first layer (a metal hard mask layer, titanium oxide: film thickness of 50 nm) are laminated in this order on a substrate (12-inch silicon substrate) in cross-sectional view. (Substrate/third layer/etching stop layer/second layer/first layer). The laminate was cut into 2 cm×2 cm in top view to prepare test samples.

Subsequently, plasma etching was performed on the obtained samples (laminates) using the first layer as a mask, and etching of the second layer was performed until a surface of the third layer was exposed to form holes (diameter/shape: 40 nm, hole shape), thereby preparing substrates for measurement having the configuration illustrated in FIG. 1 (samples after etching) (see FIG. 1).

Then, the samples after etching (substrates for measurement) were cleaned. The cleaning was performed by the following method. First, each processing solution of Examples and Comparative examples was heated to 58° C. Subsequently, each sample after etching was immersed in each processing solution of Examples and Comparative examples at 58° C. for 5 minutes. Thereafter, the sample was taken out from the processing solution, cleaned with isopropyl alcohol, and dried by nitrogen blowing. Then, how many residues remain on the sample was confirmed with a scanning electron microscope (SEM, imaging magnification: 100 k×, device name “SU-8220”, manufactured by Hitachi High-Technologies). Specifically, whether or not etching residues (titanium-based residues) were present on wall surfaces of the holes was confirmed to evaluate residue removal properties. The residue removal properties were evaluated based on the following criteria. Incidentally, corrosion to a degree that would pose a practicability problem was not observed in any of the metal layers of the substrates for measurement of Examples.

Criteria for determining the residue removal properties are as follows.

A: As a result of confirmation after the immersion by SEM under the same conditions, 95% or more of the residues confirmed by SEM before the immersion were removed.
B: As a result of confirmation after the immersion by SEM under the same conditions, 85% or more and less than 95% of the residues confirmed by SEM before the immersion were removed.
C: As a result of confirmation after the immersion by SEM under the same conditions, 80% or more and less than 85% of the residues confirmed by SEM before the immersion were removed.
D: As a result of confirmation after the immersion by SEM under the same conditions, less than 80% of the residues confirmed by SEM before the immersion were removed.

### 1-3. Evaluation of Anti-Corrosion Properties (Film Loss)

The anti-corrosion properties of Examples and Comparative examples were evaluated by the following method.

First, laminates including the respective metal layers (substrates having a film) were prepared as described below.
A laminate in which a SiN metal layer (film thickness: 20 nm) is formed on a substrate (12-inch silicon substrate) was prepared by a CVD method.
A laminate in which a W metal layer (film thickness: 100 nm) is formed on a substrate (12-inch silicon substrate) was prepared by the CVD method.
A laminate in which a Mo metal layer (film thickness: 40 nm) is formed on a substrate (12-inch silicon substrate) was prepared by a PVD method.

Subsequently, the laminates obtained (substrates having the films) were cut into 2 cm×2 cm in top view to obtain test samples (wafer coupons). Then, 80 mL of each cleaning solution of Examples and Comparative examples was poured into a 100 mL cup. Each sample was placed and immersed in the cleaning solution at the temperature and processing time shown in the table. For example, in the case of SiN in Table 2, the sample was immersed at 58° C. for 30 minutes. During the immersion, the cleaning solution was stirred at 300 rpm. After the immersion, each sample was taken out, washed with water at room temperature, and dried by nitrogen blowing.

Then, the film thicknesses of each sample before and after the immersion in the cleaning solution were measured. By determining the difference as the amount of change in film thickness, the film loss (see “film loss” in the table) was determined. For example, the film loss of the SiN film of Example 1 was 3.4 Å (Å=angstrom, see Table 2).

Measurement of the film thickness was conducted by the following methods.

The thickness of the SiN film was measured using an ellipsometer (“L115S300 STOKES WAFERSKAN”, manufactured by Gaertner Scientific Corporation). Note that the unit of film thickness is angstrom unless otherwise specified.

The thicknesses of the films other than the SiN film were measured using a scanning X-ray fluorescence spectrometer (ZSX Primus IV, manufactured by Rigaku Corporation).

The film loss of SiN (“SiN film loss”) was evaluated based on the following criteria.

A: The film loss was less than 10 Å.
B: The film loss was 10 Å or more and less than 50 Å.
C: The film loss was 50 Å or more.

The film loss of W (“W film loss”) was evaluated based on the following criteria.

A: The film loss was less than 15 Å.
B: The film loss was 15 Å or more and less than 50 Å.
C: The film loss was 50 Å or more and less than 100 Å.
D: The film loss was 100 Å or more.

The film loss of Mo (“Mo film loss”) was evaluated based on the following criteria.

A: The film loss was less than 20 Å.
B: The film loss was 20 Å or more and less than 30 Å.
C: The film loss was 30 Å or more and less than 100 Å.
D: The film loss was 100 Å or more.

Table 2 shows the composition and evaluation results of each cleaning solution of Examples and Comparative examples.

TABLE 2

| | | | | Comparative | Comparative | Comparative |
|---|---|---|---|---|---|---|
| | Example 1 | Example 2 | Example 3 | example 1 | example 2 | example 3 |
| | (COOH)₂ | H₃PO₄ | H₂SO₄ | HF | H₂O₂ | HA |
| | 3 mass % | 10 mass % | 10 mass % | 0.005 mass % | 10 mass % | 12 mass % |
| | aqueous | aqueous | aqueous | aqueous | aqueous | aqueous |
| | solution | solution | solution | solution | solution | solution |
| pKa | 1.3 | 1.75 | 0.81 | 3.17 | 12.05 | — |
| pH | 0.9 | 0.9 | 0.2 | 3.1 | 4.4 | 10 |
| Residue removal | A | A | A | A | A | A |
| properties | | | | | | |
| SiN film loss [Å] | A (3.4) | A (<0.1) | A (<0.1) | C (65.4) | A (3.19) | A (<0.1) |
| 58deg. C. −30 min | | | | | | |
| W film loss [Å] | A (11.9) | A (4.3) | A (3.6) | B (25.9) | D (1017) | C (45) |
| 58deg. C. −10 min | | | | | | |
| Mo film loss [Å] | A (8.7) | A (16.2) | A (11.5) | A (11.9) | D (373.1) | C (35.9) |
| 58deg. C. −5 min | | | | | | |

(COOH)₂: oxalic acid, H₃PO₄: phosphoric acid, H₂SO₄: sulfuric acid,
HF: hydrogen fluoride, H₂O₂: hydrogen peroxide water, HA: hydroxylamine

### 2. Test 2

### 2-1. Preparation of Cleaning Solution

### Example 4

A cleaning solution was obtained by blending oxalic acid ((COOH)₂) and water in the proportions shown in Table 2. Example 4 is a cleaning solution containing only 3% by mass of oxalic acid as a cleaning agent and 97% by mass of water.

### Examples 5, 6, Comparative Examples 4 to 9

Cleaning solutions were obtained in the same manner as in Example 4 except that the cleaning agent and water were blended at the proportions shown in Tables 3 and 4. For example, Example 5 is a cleaning solution containing 3% by mass of phosphoric acid and 97% by mass of water.

### <pKa of Oxoacid>

The pKa of oxoacid (for example, phosphoric acid in Example 5) was determined by the same method as in “1. Test 1” above.

### <Measuring Method of the pH of Cleaning Solution>

The pH of each cleaning solution was measured by the same method as in “1. Test 1” above.

### <Oxidation-Reduction Potential (ORP) of Cleaning Solution>

The ORP of each cleaning solution was measured using a pH/ORP meter (portable pH meter “ORION STAR A324”, manufactured by Thermo Scientific) under a temperature condition of 22° C.

### 2-2. Evaluation of Removability of Titanium-Based Residue (Residue Removal Properties)

Test samples were prepared in the same manner as in “1-2. Evaluation of removability of titanium-based residue (residue removal properties)” in “1. Test 1” above, and the removability of titanium-based residue was evaluated.

### 2-3. Evaluation of Anti-Corrosion Properties (Film Loss)

Test samples were prepared in the same manner as in “1-3. Evaluation of anti-corrosion properties (film loss)” in “1. Test 1” above, and the anti-corrosion properties were evaluated.

Tables 3 and 4 show the composition and evaluation results of each cleaning solution of Examples and Comparative examples.

TABLE 3

| | Example 4 | Example 5 | Example 6 |
|---|---|---|---|
| | (COOH)₂ | H₃PO₄ | H₂SO₄ |
| | 3 mass % | 3 mass % | 3 mass % |
| | aqueous | aqueous | aqueous |
| | solution | solution | solution |
| Valence | 2 | 3 | 2 |
| pKa | 1.3 | 1.75 | 0.81 |
| pH | 0.9 | 1.3 | 0.6 |
| ORP [mV] | 484 | 530 | 530 |
| Residue removal | A | A | A |
| properties | | | |
| SiN film loss [Å] | A | A | A |
| 58deg. C.-30 min | (3.4) | (4.72) | (5.28) |
| W film loss [Å] | A | A | A |
| 58deg. C.-10 min | (11.9) | (10.7) | (8.5) |
| Mo film loss [Å] | A | A | A |
| 58deg. C.-5 min | (8.7) | (9.06) | (15.7) |

| | Comparative | Comparative | Comparative | Comparative | Comparative | Comparative |
|---|---|---|---|---|---|---|
| | example 4 | example 5 | example 6 | example 7 | example 8 | example 9 |
| | HA | B(OH)₃ | HCOOH | CH₃COOH | HNO₃ | MSA |
| | 12 mass % | 3 mass % | 3 mass % | 3 mass % | 3 mass % | 3 mass % |
| | aqueous | aqueous | aqueous | aqueous | aqueous | aqueous |
| | solution | solution | solution | solution | solution | solution |
| Valence | 0 | 3 | 1 | 1 | 1 | 1 |
| pKa | — | 9.2 | 3.8 | 4.8 | −1.3 | 0.4 |
| pH | 10 | 3.7 | 1.5 | 2.1 | 0.6 | 0.7 |
| ORP [mV] | −202 | 434 | 284 | 466 | 514 | 530 |
| Residue removal | A | D | D | D | D | D |
| properties | | | | | | |
| SiN film loss [Å] | A (<0.1) | ND | ND | ND | ND | ND |
| 58deg. C. −30 min | | | | | | |
| W film loss [Å] | C (45) | ND | ND | ND | ND | ND |
| 58deg. C. −10 min | | | | | | |
| Mo film loss [Å] | C (35.9) | ND | ND | ND | ND | ND |
| 58deg. C. −5 min | | | | | | |

HA: hydroxylamine, B(OH)₃: boric acid, HCOOH: formic acid, CH₃COOH: acetic acid, HNO₃: nitric acid, MSA: methanesulfonic acid, HCl: hydrochloric acid. Note that since hydroxylamine (HA) is not an acid, the “valence” in the table is marked as “0”. Furthermore, in Comparative examples 5 to 9, the film thickness could not be accurately measured because their residue removal properties were “D”. Hence, in Comparative Examples 5 to 9, the film loss could not be determined. Therefore, the film loss of Comparative Examples 5 to 9 is marked as “ND” in the table.

### 3. Test 3

### 3-1. Preparation of Cleaning Solution

### Examples 7, 8

A cleaning solution was obtained by blending oxalic acid ((COOH)₂), 5-aminotetrazole, and water in the proportions shown in Table 5. For example, Example 8 is a cleaning solution containing 3% by mass of oxalic acid and 1% by mass of 5-aminotetrazole as a cleaning agent, and 96% by mass of water.

### <pKa of Oxoacid>

The pKa of oxoacid (for example, oxalic acid in Example 7 and Example 8) was determined by the same method as in “1. Test 1” above.

### <Measuring Method of the pH of Cleaning Solution>

The pH of each cleaning solution was measured by the same method as in “1. Test 1” above.

### 3-2. Evaluation of Removability of Titanium-Based Residue (Removability of Etching Residue)

Test samples were prepared in the same manner as in “1-2. Evaluation of removability of titanium-based residue” in “1. Test 1” above, and the removability of titanium-based residue was evaluated.

### 3-3. Evaluation of Anti-Corrosion Properties (Film Loss)

The anti-corrosion properties of Examples and Comparative examples were evaluated by the following method.

First, laminates including the respective metal layers (substrates having a film) were prepared as described below.

A laminate in which a SiN metal layer (film thickness: 20 nm) is formed on a substrate (12-inch silicon substrate) was prepared by a CVD method.

A laminate in which a W metal layer (film thickness: 100 nm) is formed on a substrate (12-inch silicon substrate) was prepared by the CVD method.

A laminate in which a Mo metal layer (film thickness: 40 nm) is formed on a substrate (12-inch silicon substrate) was prepared by a PVD method.

A laminate in which a Co metal layer (film thickness: 20 nm) is formed on a substrate (12-inch silicon substrate) was prepared by the CVD method.

Subsequently, the laminates obtained (substrates having the films) were cut into 2 cm×2 cm in top view to obtain test samples (wafer coupons). Then, 80 mL of each cleaning solution of Examples and Comparative examples was poured into a 100 mL cup. Each sample was placed and immersed in the cleaning solution at the temperature and processing time shown in the table. During the immersion, the cleaning solution was stirred at 300 rpm. For example, in the case of SiN in Table 5, the sample was immersed at 58° C. for 30 minutes. After the immersion, each sample was taken out, washed with water at room temperature, and dried by nitrogen blowing.

Further, test samples were prepared in the same manner as in “1-3. Evaluation of anti-corrosion properties (film loss)” in “1. Test 1” above, and the anti-corrosion properties were evaluated.

Note that the anti-corrosion properties of Co (film loss) were evaluated by means of a relative ratio with the standard being “100”. The value of the film loss in Example 7 containing no anticorrosive agent was assumed to be 100 as the standard, and the film loss of Co in Example 8 was determined as a relative ratio thereof. For example, the film loss in Example 8 in the table means 30/100 of the film loss in Example 7.

Table 5 shows the composition and evaluation results of each cleaning solution of Examples.

TABLE 5

| | Example 7 | Example 8 |
|---|---|---|
| Oxalic acid | 3 mass % | 3 mass % |
| 5-Aminotetrazole | 0 mass % | 1 mass % |
| Water | 97 mass % | 96 mass % |
| pKa | 1.3 | 1.3 |
| pH | 0.90 | 0.94 |
| Residue removal | A | A |
| properties | | |
| SiN film loss [Å] | A | A |
| 58deg. C.-30 min | (3.4) | (3.2) |
| W film loss [Å] | A | A |
| 58deg. C.-10 min | (11.9) | (817.3) |
| Mo film loss [Å] | A | A |
| 58deg. C.-5 min | (8.7) | (13) |
| Co film loss relative ratio | 100 | 30 |
| 58deg. C.-30 s | | |

### 4. Test 4

### 4-1. Preparation of Cleaning Solution

### Examples 9 to 11

Cleaning solutions of the compositions listed in Table 6 were prepared. For example, Example 9 is a cleaning solution containing 3% by mass of oxalic acid as an oxo acid, 0% by mass of organic solvent, and 97% by mass of water. Example 10 is a cleaning solution containing 3% by mass of oxalic acid as an oxo acid, 40% by mass of hexylene glycol (HG) as an organic solvent, and 57% by mass of water.

### <pKa of Oxoacid>

The pKa of oxoacid (for example, oxalic acid in Examples 9 to 11) was determined by the same method as in “1. Test 1” above.

### <Measuring Method of the pH of Cleaning Solution>

The pH of each cleaning solution was measured by the same method as in “1. Test 1” above.

### 4-2. Evaluation of Removability of Titanium-Based Residue (Residue Removal Properties)

Test samples were prepared in the same manner as in “3-2. Evaluation of removability of titanium-based residue” in “3. Test 3” above, and the removability of titanium-based residue was evaluated.

### 4-3. Evaluation of Anti-Corrosion Properties (Film Loss)

Test samples were prepared in the same manner as in “3-3. Evaluation of anti-corrosion properties (film loss)” in “3. Test 3” above, and the anti-corrosion properties were evaluated.

Note that the anti-corrosion properties of Co (film loss) were evaluated by means of a relative ratio with the standard being “100”. The value of the film loss in Example 9 containing no anticorrosive agent was assumed to be 100 as the standard, and the film loss in Examples 10 and 11 was determined as a relative ratio thereof. For example, the film loss in Example 10 in the table means 69/100 of the film loss in Example 7.

Table 6 shows the composition and evaluation results of each cleaning solution of Examples.

TABLE 6

| | Example 9 | Example 10 | Example 11 |
|---|---|---|---|
| Oxalic acid | 3 mass % | 3 mass % | 3 mass % |
| Hexylene glycol | 0 mass % | 40 mass % | 50 mass % |
| Water | 97 mass % | 57 mass % | 47 mass % |
| pKa | 1.3 | 1.3 | 1.3 |
| pH | 0.90 | 1.02 | 1.15 |
| Residue removal | A | A | A |
| properties | | | |
| SiN film loss [Å] | A | A | A |
| 58deg. C.-30 min | (3.4) | (2.8) | (3.1) |
| W film loss [Å] | A | B | B |
| 58deg. C.-10 min | (11.9) | (15.6) | (37.4) |
| Mo film loss [Å] | A | B | B |
| 58deg. C.-5 min | (8.7) | (33.0) | (43.9) |
| Co film loss relative ratio | 100 | 69 | 6 |
| 58deg. C.-30 s | | | |

From the above, it was at least confirmed that the cleaning solutions according to Examples can efficiently remove a titanium-based residue and are excellent in anti-corrosion properties. Such cleaning solutions can be suitably used in a method for cleaning a semiconductor substrate, and a method for manufacturing a semiconductor.

The present application claims priority to U.S. Provisional Application No. 63/509,930, filed with the United States Patent and Trademark Office on Jun. 23, 2023, the contents of which are incorporated herein by reference.

### EXPLANATION OF REFERENCE SIGNS

10: Substrate
20: Metal wiring layer
30: Etching stop layer
40: Interlayer insulating film
50: Hard mask layer
60: Etching residue
100: Semiconductor element (semiconductor substrate)

1. A cleaning solution, comprising:
an oxoacid having an acid dissociation constant pKa of less than 5.0 and a valence of two or more,
wherein a value of pH of the cleaning solution is smaller than the acid dissociation constant.

2. The cleaning solution according to claim 1,
wherein the value of pH of the cleaning solution is 5.0 or less.

3. The cleaning solution according to claim 1,
wherein the oxoacid is at least one selected from the group consisting of oxalic acid, malonic acid, H₃PO₄, and sulfuric acid.

4. The cleaning solution according to claim 1,
wherein a concentration of the oxoacid is from 0.005 to 20% by mass.

5. The cleaning solution according to claim 1, further comprising:
at least one selected from the group consisting of a nitrogen-containing heterocycle-containing compound, a mercapto group-containing compound, an aliphatic amine compound, a zwitterionic compound, and a salt thereof, as an anticorrosive agent.

6. The cleaning solution according to claim 1, further comprising:
water as a solvent.

7. The cleaning solution according to claim 1, further comprising:
at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent, as a solvent.

8. The cleaning solution according to claim 1,
wherein the cleaning solution does not contain hydrogen peroxide, hydrogen fluoride, and hydroxylamine.

9. The cleaning solution according to claim 1,
wherein the cleaning solution is a cleaning solution for a semiconductor substrate,
the semiconductor substrate comprises a substrate, and a film formed on the substrate, and
the film comprises titanium or a titanium-based alloy.

10. A method for cleaning a semiconductor substrate having a protective film, comprising:
removing an impurity from the semiconductor substrate by bringing the cleaning solution according to claim 1 into contact with the protective film.

11. A method for manufacturing a semiconductor, comprising:
preparing a substrate having a protective film;
etching the protective film; and
after the etching, removing an impurity from the substrate by bringing the cleaning solution according to claim 1 into contact with the substrate.
